(19) United States
(12) Patent Application Publication
(10) Pub. No.: US 2017/0145553 A1
(43) Pub. Date: May 25, 2017

(54) PRE-COATED SHIELD USING IN VHF-RF PVD CHAMBERS

(71) Applicant: Applied Materials, Inc., Santa Clara, CA (US)

(72) Inventors: Zhendong LIU, Tracy, CA (US); Wenting HOU, Sunnyvale, CA (US); Jianxin LEI, Fremont, CA (US); Donny YOUNG, Cupertino, CA (US); William M. LU, Sunnyvale, CA (US)

(21) Appl. No.: 15/347,582

(22) Filed: Nov. 9, 2016

Related U.S. Application Data
(60) Provisional application No. 62/259,544, filed on Nov. 24, 2015.

(51) Int. Cl. C23C 4/134; C23C 16/455; C23C 16/50; C25D 17/00; C23C 18/48; C23C 14/34; C25D 3/02; C23C 16/44; C23C 18/31

(52) U.S. Cl. CPC C23C 4/134; C23C 16/4404; C23C 16/45525; C23C 16/50; C23C 18/31; C23C 18/48; C23C 14/34; C25D 3/02; C25D 17/00

(57) ABSTRACT

Implementations of the present disclosure relate to an improved shield for use in a processing chamber. In one implementation, the shield includes a hollow body having a cylindrical shape that is substantially symmetric about a central axis of the body, and a coating layer formed on an inner surface of the body. The coating layer is formed the same material as a sputtering target used in the processing chamber. The shield advantageously reduces particle contamination in films deposited using RF-PVD by reducing arcing between the shield and the sputtering target. Arcing is reduced by the presence of a coating layer on the interior surfaces of the shield.

### CROSS-REFERENCE TO RELATED APPLICATIONS

This application claims priority to U.S. provisional patent application Ser. No. 62/259,544, filed Nov. 24, 2015, which is herein incorporated by reference.

### FIELD

Implementations of the present disclosure generally relate to a shield for use in a processing chamber.

### BACKGROUND

In current radio frequency physical vapor deposition (RF-PVD) chambers, a grounded shield is typically mounted to the main body of the PVD chamber and extended over most of the chamber sidewall enclosing the processing space between a pedestal and a sputtering target. The shield prevents excess material sputtering from the target from contaminating the remainder of the RF-PVD chamber. The inventors have observed that the potential difference between the plasma and the shield will cause positive ions within the plasma to accelerate toward the grounded shield. The material comprising the shield (e.g., aluminum) may flake off as a result of the ion bombardment and contaminate the substrate surface. The amount of aluminum contamination becomes worse when higher RF power and higher pressure are utilized.

Therefore, there is a need for an improved shield.

### SUMMARY

A shield for use in a physical vapor deposition processing chamber is described herein. In one example, the shield includes a hollow body having a cylindrical shape that is substantially symmetric about a central axis thereof. The body has an inner surface and an outer surface. A coating layer is formed on the inner surface of the body. The coating layer is fabricated from a metal, a metal oxide, metal alloy, or magnetic material.

In another implementation, a shield for use in a physical vapor deposition processing chamber is provided. The shield includes an elongated cylindrical body configured to surround a processing volume between a sputtering target and a substrate support and protect sidewalls of the processing chamber from deposition. The body is fabricated from aluminum. A coating layer is formed on an inner surface of the elongated cylindrical body, wherein the coating layer comprises cobalt or cobalt alloy.

In yet another implementation, a method for treating a shield for use in a physical vapor deposition processing chamber is provided. The shield includes an elongated cylindrical body configured to protect sidewalls of the processing chamber from deposition. The method includes depositing a coating layer on an inner surface of the body. The coating layer is fabricated from a metal, a metal oxide, metal alloy, or magnetic material.

### BRIEF DESCRIPTION OF THE DRAWINGS

Implementations of the present disclosure, briefly summarized above and discussed in greater detail below, can be understood by reference to the illustrative implementations of the disclosure depicted in the appended drawings. It is to be noted, however, that the appended drawings illustrate only typical implementations of this disclosure and are therefore not to be considered limiting of its scope, for the disclosure may admit to other equally effective implementations.

FIG. 1 depicts a schematic, cross-sectional view of a physical vapor deposition chamber having a pre-coated shield.

FIG. 2 depicts a schematic, cross-sectional view of a portion of the pre-coated shield depicted in FIG. 1.

FIG. 3 depicts a method for treating a shield.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

The present disclosure relates to a pre-coated shield for use in a processing chamber. The improved shield advantageously reduces particle contamination in films deposited using RF-PVD by reducing arcing between the shield and a sputtering target. Arcing is reduced by the presence of a coating layer on the interior surfaces of the shield. The coating layer is formed from the same material as the sputtering target.

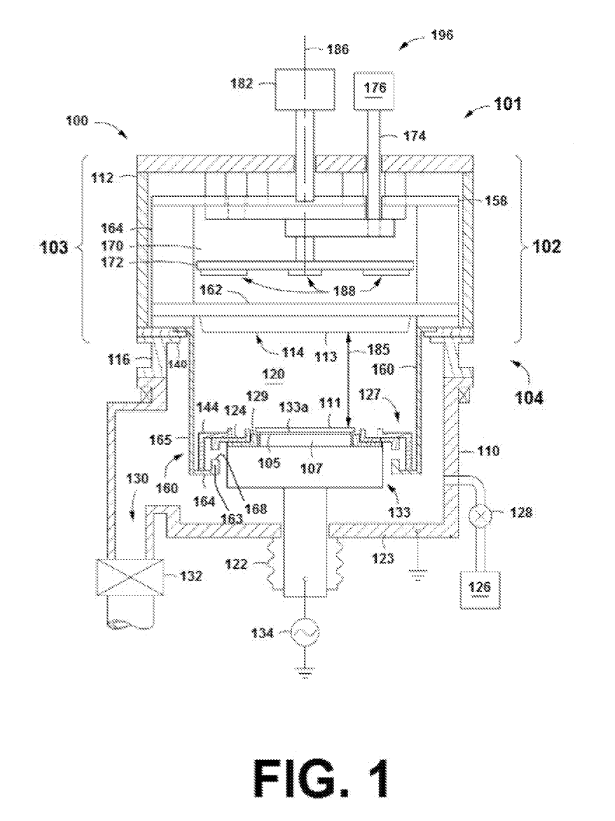

FIG. 1 depicts a schematic, cross-sectional view of a physical vapor deposition chamber (processing chamber 100) having a pre-coated shield 160. The configuration of the PVD chamber is illustrative and PVD chambers, or other process chambers, having other configurations may also benefit from modification in accordance with the teachings provided herein. Examples of suitable PVD chambers that may be adapted to benefit from the present disclosure include any of the Cirrus®, AURA®, or AVENIR® lines of PVD processing chambers, commercially available from Applied Materials, Inc., of Santa Clara, Calif. Other processing chambers from Applied Materials, Inc. or other manufacturers may also benefit from implementations of the disclosure disclosed herein.

The processing chamber 100 includes a chamber lid 101 disposed atop a chamber body 104. The lid 101 is removable from the chamber body 104. The chamber lid 101 includes a sputtering target assembly 102 and a grounding assembly 103 disposed about the sputtering target assembly 102. The chamber lid 101 rests on a ledge 140 of an upper grounded enclosure wall 116, which is part of the chamber body 104. The upper grounded enclosure wall 116 may provide a portion of an RF return path defined between the upper grounded enclosure wall 116 and the grounding assembly 103 of the chamber lid 101. However, other RF return paths are possible.

The target assembly 102 may include a source distribution plate 158 opposing a backside of the sputtering target 114 and electrically coupled to the sputtering target 114 along a peripheral edge of the sputtering target 114. The sputtering target 114 may comprise a source material 113 to be deposited on a substrate 111 during a deposition process. The deposition process may be performed to deposit a metal, metal oxide, metal alloy, magnetic material, or other suitable material. In some implementations, the sputtering target 114 may include a backing plate 162 to support the source material 113. The backing plate 162 may comprise a conductive material, such as copper, copper-zinc, copper-chrome, or the same material as the sputtering target, such that RF, and optionally DC, power can be coupled to the source material 113 via the backing plate 162. Alternatively, the backing plate 162 may be non-conductive and may include conductive elements (not shown) such as electrical feedthroughs or the like.

A magnetron assembly 196 may be disposed at least partially within a cavity 170. The magnetron assembly provides a rotating magnetic field proximate the sputtering target to assist in plasma processing within the process chamber 104. The magnetron assembly 196 may include a motor 176, a motor shaft 174, and a rotatable magnet (e.g., a plurality of magnets 188 coupled to a magnet support member 172).

The chamber body 104 contains a substrate support 133 having a substrate support surface 133a for receiving the substrate 111 thereon. The substrate support 133 is configured to support a substrate such that a center of the substrate 111 is aligned with a central axis 186 of the processing chamber 100. The substrate support 133 may be located within a lower grounded enclosure wall 110, which may be a wall of the chamber body 104. The lower grounded enclosure wall 110 may be electrically coupled to the grounding assembly 103 of the chamber lid 101 such that an RF return path is provided to an RF power source 182 disposed above the chamber lid 101. The RF power source 182 may provide RF energy to the target assembly 102.

The substrate support surface 133a faces a principal surface of the sputtering target 114 and may be raised above the rest of substrate support 133. The substrate support surface 133a supports the substrate 111 for processing. The substrate support 133 may include a dielectric member 105 which defines the substrate support surface 133a. In some implementations, the substrate support 133 may include one or more conductive members 107 disposed below the dielectric member 105.

The substrate support 133 supports the substrate 111 in a processing volume 120 of the chamber body 104. The processing volume 120 is a portion of the inner volume of the chamber body 104 that is used for processing the substrate 111 and may be separated from the remainder of the inner volume (e.g., a non-processing volume) during processing of the substrate 111 (for example, via a process kit 127). The processing volume 120 is defined as the region above the substrate support 133 during processing (for example, between the sputtering target 114 and the substrate support 133 when in a processing position).

A bellows 122 connected to a bottom chamber wall 123 may be provided to maintain a separation of the inner volume of the chamber body 104 from the atmosphere outside of the chamber body 104.

One or more gases may be supplied from a gas source 126 through a mass flow controller 128 into the lower part of the chamber body 104. An exhaust port 130 may be provided and coupled to a pump (not shown) via a valve 132 for exhausting the interior of the chamber body 104 and to facilitate maintaining a desired pressure inside the chamber body 104.

An RF bias power source 134 may be coupled to the substrate support 133 in order to induce a negative DC bias on the substrate 111. In addition, in some implementations, a negative DC self-bias may form on the substrate 111 during processing. In some implementations, RF energy supplied by the RF bias power source 134 may range in frequency from about 2 MHz to about 60 MHz, for example, non-limiting frequencies such as 2 MHz, 13.56 MHz, 40 MHz, or 60 MHz can be used.

A process kit 127 may include one or more of an annular body 129, a first ring 124, a second ring 144, and the shield 160. The process kit 127 surrounds the processing volume 120 of the chamber body 104, thus providing the chamber body 104 and other chamber components from damage and/or contamination during processing. The shield 160 extends downwardly along the walls 116 and the lower grounded enclosure wall 110 to below the top surface of the substrate support 133 when the substrate support 133 is in its lowest processing position, and returns upwardly until reaching or near the top surface of the substrate support 133. The shield 160 thus forms a U-shaped portion at the bottom of the shield 160.

The shield 160 may be coupled to a portion of the upper grounded enclosure wall 116 of the chamber body 104, for example to the ledge 140. In other implementations, the shield 160 may be coupled to the chamber lid 101, for example via a retaining ring 175. The shield 160 may be coupled to ground, for example, via the ground connection of the chamber body 104. The shield 160 may comprise any suitable conductive material, such as aluminum, stainless steel, copper, or the like. If desired, the shield 160 may be fabricated by depositing a thick aluminum layer on a core material. As will be discussed in more detail below, the shield 160 is pre-coated with the same material comprising the sputtering target material prior to installation in the processing chamber 100. By using a pre-coated shield 160, the aluminum material comprising the shield 160 is not exposed during processing, thereby reducing the possibility of aluminum contamination on substrate surface.

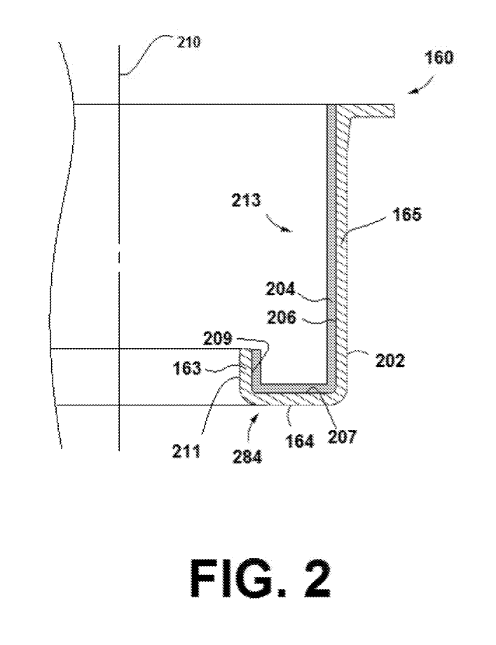

FIG. 2 depicts a schematic, cross-sectional view of a portion of the shield 160 according to implementations of the present disclosure. The shield 160 has a hollow body 202. The hollow body 202 has a cylindrical shape that is substantially symmetric about a central axis 210 of the shield 160. The hollow body 202 is axially aligned the central axis 186 of the processing chamber 100. The shield 160 has a first annular leg 165, a second annular leg 163, and a horizontal leg 164. The horizontal leg 164 is radially extended and connects the second annular leg 163 to the first annular leg 165 at the lower portion of the first annular leg 165. The second annular leg 163 is relatively shorter than the first annular leg 165, forming a U- or L-shaped portion at the bottom of the shield 160. Alternatively, the bottom-most portion of the shield 160 need not be a U-shaped, and may have another suitable shape.

The body 202 of the shield 160 may be fabricated from a single mass of material to form a one-piece body or two or more components welded together to form a one piece body. Providing a one-piece body may advantageously eliminate additional surfaces, which may otherwise contribute to flaking of deposited materials if the shield 160 is formed of multiple pieces. In one implementation, the shield 160 is a one-piece body formed of aluminum. In another implementation, the shield 160 is a one-piece body formed of stainless steel coated with aluminum. Alternatively, the shield 160 may be any of a core material coated with aluminum.

The shield 160 has a coating layer 204 formed on an interior surface 213 of the shield 160. The interior surface 213 referred herein includes the exposed surfaces of the shield 160 facing the substrate support 133. For example, in some implementations, the coating layer 204 disposed may extend along the longitudinal direction of a portion or entire portion of the first annular leg 165 on an inner surface 206 of the first annular leg 165. In some implementations, the coating layer 204 may extend to an upper surface 207 of the horizontal leg 164, or even extend to an inner surface 209 of the second annular leg 163. In most cases, the exterior surface of the shield 160 is free from the coating layer. In some implementations, the coating layer 204 may be formed on an outer surface 211 of the second annular leg 163. If desired, the coating layer 204 may be formed on all exposed surfaces of the shield 160.

In various implementations, the coating layer 204 includes the same material as the sputtering target 114 (FIG. 1). For example, if the sputtering target 114 is fabricated from cobalt or a cobalt alloy, the coating layer 204 will also be cobalt or a cobalt alloy. Therefore, the coating layer 204 includes the same material as the film to be deposited on the substrate surface from the sputtering target 114. The coating layer 204 may be at least 99.95% pure.

Depending upon the material of the sputtering target 114, the coating layer 204 may contain a metal, a metal oxide, metal alloy, magnetic material, or the like. In one implementation, the coating layer 204 is cobalt, cobalt silicide, nickel, nickel silicide, platinum, tungsten, tungsten silicide, tungsten nitride, tungsten carbide, copper, chrome, tantalum, tantalum nitride, tantalum carbide, titanium, titanium oxide, titanium nitride, lanthanum, zinc, alloys thereof, silicides thereof, derivatives thereof, or any combinations thereof.

In some exemplary examples, the material of the coating layer 204 is cobalt, a cobalt alloy, nickel, a nickel alloy, a nickel-platinum alloy, tungsten, a tungsten alloy, or other material comprising the sputtering target 114. The coating layer 204 may be a single layer of the material listed above, or may be multiple layers of the same material or different materials listed above. In examples where the coating layer 204 is a nickel-platinum alloy, the nickel-platinum alloy may contain a nickel concentration by weight within a range from about 80% to about 98%, such as from about 85% to about 95%, and a platinum concentration by weight within a range from about 2% to about 20%, such as from about 5% to about 15%. In one exemplary implementation, the coating layer 204 comprises nickel-platinum alloys such as NiPt5% (about 95 wt % of nickel and about 5 wt % of platinum), NiPt10% (about 90 wt % of nickel and about 10 wt % of platinum), or NiPt15% (about 85 wt % of nickel and about 15 wt % of platinum).

The overall thickness of the coating layer 204 may be within a range from about 3 μm to about 110 μm, such as about 5 μm to about 110 μm, about 10 μm to about 110 μm, about 15 μm to about 110 μm, about 20 μm to about 110 μm, about 25 μm to 110 μm, about 30 μm to about 110 μm, about 50 μm to about 110 μm, about 70 μm to about 110 μm, about 90 μm to about 110 μm. In one implementation, the coating layer 204 has a thickness of about 10 μm to about 25 μm. The thickness of the coating layer 204 may vary depending upon the processing requirements, or the desired coating life.

The coating layer 204 may be applied to the shield 160 prior to installation of the shield 160 in the processing chamber 100. The coating layer 204 may be deposited, plated, or otherwise formed on the interior surface 206 of the shield 160 using any suitable technique. For example, the coating layer 204 may be formed on the interior surface 206 by a deposition process, such as a plasma spray process, a sputtering process, a PVD process, a CVD process, a PE-CVD process, an ALD process, a PE-ALD process, an electroplating or electrochemical plating process, an electroless deposition process, or derivatives thereof. In other implementations, the coating layer 204 may be applied to the shield 160 prior to processing a substrate within the processing chamber 100.

Prior to formation of the coating layer 204 onto the shield 160, the interior surface 206 or at least the exposed surfaces of the shield 160 (to be deposited with the coating layer 204) may be roughened to have any desired texture by abrasive blasting, which may include, for example, bead blasting, sand blasting, soda blasting, powder blasting, and other particulate blasting techniques. The blasting may also enhance the adhesion of the coating layer 204 to the shield 160. Other techniques may be used to roughen the interior surface 206 or at least the exposed surfaces of the shield 160 including mechanical techniques (e.g., wheel abrasion), chemical techniques (e.g., acid etch), plasma etch techniques, and laser etch techniques. The interior surface 206 or at least the exposed surfaces of the shield 160 (to be deposited with the coating layer 204) may have a mean surface roughness within a range from about 80 microinches (μin) to about 500 μin, such as from about 100 μin to about 400 μin, for example from about 120 μin to about 220 μin or from about 200 μin to about 300 μin. If desired, these roughing techniques may be applied to the coating layer 204 after the coating layer 204 is applied to the shield 160.

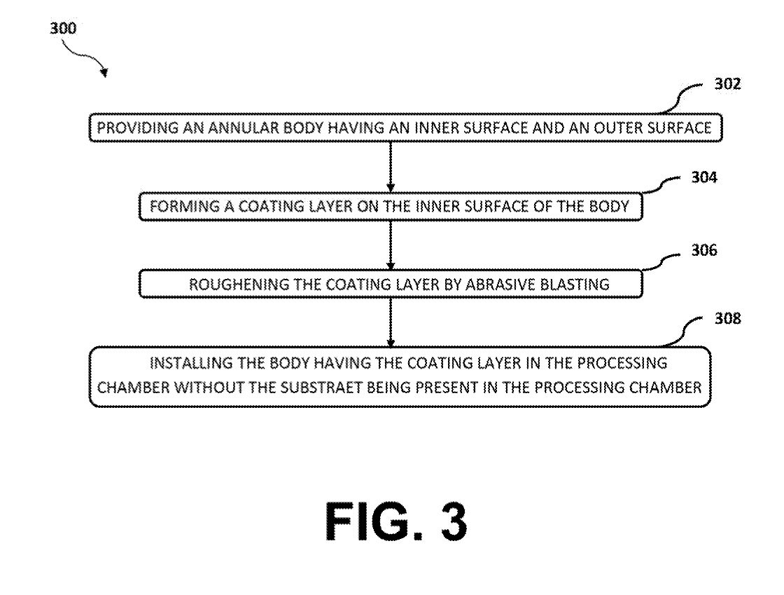

FIG. 3 is a method 300 for treating a shield for use in a processing chamber, such as the shield 160 and the processing chamber 100, described above. The method 300 starts at block 302 by providing an annular body defining an opening surrounded by the body. Specifically, the body is a hollow body having a cylindrical shape, and is fabricated to have a first annular leg, a second annular leg relatively shorter than the first annular leg, and a horizontal leg connecting the second annular leg to the first annular leg at the lower portion of the first annular leg, as generally shown in FIG. 2. The body is manufactured from aluminum, stainless steel, aluminum oxide, aluminum nitride, or ceramic. In one implementation, the body is a one-piece body formed of aluminum. In another implementation, the body is a one-piece body formed of stainless steel coated with aluminum. The body has an inner diameter selected to accommodate the size of a substrate support, such as the substrate support 133 shown in FIG. 1.

At block 304, a coating layer is formed on interior surface of the body by a deposition process, such as such as a plasma spray process, a sputtering process, a PVD process, a CVD process, a PE-CVD process, an ALD process, a PE-ALD process, an electroplating or electrochemical plating process, an electroless deposition process, or derivatives thereof. The interior surface of the body includes exposed surfaces facing the substrate support in the processing chamber, such as the inner surface 206 of the first annular leg 165, the upper surface 207 of the horizontal leg 164, the inner surface 209 of the second annular leg 163, and/or the outer surface 211 of the second annular leg 163 as shown in FIGS. 1 and 2. In one exemplary implementation, the coating layer is formed on the interior surface of the body by plasma spraying. The plasma spray may be performed in vacuum environment to enhance the purity and density of the coating. The coating layer is or contains the same material as the film to be deposited on a substrate surface from a sputtering target disposed within the processing chamber. In one implementation, the coating layer is formed from a material that is at least 99.95% as pure as the sputtering target material. The coating layer may contain a metal, a metal oxide, metal alloy, magnetic material, or the like, as discussed above with respect to FIG. 2. In one implementation, the coating layer is formed from cobalt or cobalt alloy. The coating layer is deposited to have a thickness of about 2 μm to about 35 μm, for example, about 5 μm to about 25 μm.

At block 306, the coating layer is roughened to a desired texture by abrasive blasting, which may include, for example, bead blasting, sand blasting, soda blasting, powder blasting, and other particulate blasting techniques. Alternatively, the coating layer may be textured by another technique, such as but not limited to wet etching, dry etching, and energy beam texturing, among others.

At block 308, the body having the coating layer deposited on the interior surfaces is installed in the processing chamber, prior to processing a substrate within the processing chamber (i.e., the substrate is not being present in the processing chamber).

Benefits of the present disclosure include a pre-coated shield that can effectively reduce the generation of contaminating particles on the substrate surface without significantly increasing the processing or hardware cost. The shield advantageously reduces particle contamination in films deposited using RF-PVD processes by reducing arcing between the shield and a sputtering target. Arcing is reduced by the presence of a coating layer on the interior surfaces of the shield disposed surround the processing volume of the chamber body. The coating layer is treated or bead blasted to substantially prevent particles, e.g., aluminum particles, from flaking off of the shield, which would otherwise contaminate a substrate being processed. Particularly, the coating layer comprises the same material as the sputtering target or the film layer to be formed on the substrate surface. Therefore, even if the coating materials are flaking off of the shield during processing of the substrate, the contamination of the substrate surface is minimized. The improved shield has been shown to be able to reduce aluminum contamination on the substrate surface from 5.9×10¹² atoms/cm² to 3.1×10¹⁰ atoms/cm² or less. The deposition process using the improved shield also shows higher bottom coverage (e.g., 70% or above measuring at the center) and less overhang for step coverage of small structures having a high depth-to width ratio of 5:1 or higher, such as about 10:1 or higher, for example about 50:1.

While the foregoing is directed to implementations of the present disclosure, other and further implementations of the disclosure may be devised without departing from the basic scope thereof.

1. A shield for use in a physical vapor deposition processing chamber, comprising:
a hollow body having a cylindrical shape that is substantially symmetric about a central axis of the hollow body, the body having an inner surface and an outer surface; and
a coating layer formed on the inner surface of the body, the coating layer comprising a metal, a metal oxide, metal alloy, or magnetic material.

2. The shield of claim 1, wherein the outer surface of the body is free from the coating layer.

3. The shield of claim 1, wherein the coating layer is formed from cobalt, cobalt silicide, nickel, nickel silicide, platinum, tungsten, tungsten silicide, tungsten nitride, tungsten carbide, copper, chrome, tantalum, tantalum nitride, tantalum carbide, titanium, titanium oxide, titanium nitride, lanthanum, zinc, alloys thereof, silicides thereof, derivatives thereof, or any combinations thereof.

4. The shield of claim 1, wherein the coating layer is formed from cobalt or cobalt alloy.

5. The shield of claim 1, wherein the body is formed of aluminum, stainless steel, aluminum oxide, aluminum nitride, or ceramic, or any combinations thereof.

6. The shield of claim 5, wherein the body is formed of aluminum and the coating layer is formed of cobalt or cobalt alloy.

7. The shield of claim 1, wherein the coating layer has a thickness of about 2 μm to about 35 μm.

8. A shield for use in a physical vapor deposition processing chamber, the shield comprising an elongated cylindrical body configured to surround a processing volume between a sputtering target and a substrate support and protect sidewalls of the processing chamber from deposition, and the body is fabricated from aluminum, wherein the improvement comprising:
a coating layer formed on an inner surface of the elongated cylindrical body, wherein the coating layer comprises cobalt or cobalt alloy.

9. The shield of claim 8, wherein coating layer is formed of the same material as the sputtering target.

10. The shield of claim 8, wherein the coating layer has a thickness of about 2 μm to about 35 μm.

11. The shield of claim 8, wherein the coating layer has a mean surface roughness of about 80 μin to about 500 μin.

12. The shield of claim 8, wherein the body comprises:
a first annular leg;
a second annular leg, the second annular leg is relatively shorter than the first annular leg; and
a horizontal leg connecting the second annular leg to the first annular leg at a lower portion of the first annular leg.

13. The shield of claim 12, wherein an outer surface of the first annular leg is free from the coating layer.

14. A method for treating a shield for use in a physical vapor deposition processing chamber, the shield comprising an elongated cylindrical body configured to protect sidewalls of the processing chamber from deposition, comprising:
depositing a coating layer on an inner surface of the body, the coating layer comprises a metal, a metal oxide, metal alloy, or magnetic material.

15. The method of claim 14, wherein the body is formed of aluminum, stainless steel, aluminum oxide, aluminum nitride, or ceramic, or any combinations thereof.

16. The method of claim 14, wherein the coating layer is formed of a material comprising cobalt, cobalt silicide, nickel, nickel silicide, platinum, tungsten, tungsten silicide, tungsten nitride, tungsten carbide, copper, chrome, tantalum, tantalum nitride, tantalum carbide, titanium, titanium oxide, titanium nitride, lanthanum, zinc, alloys thereof, silicides thereof, derivatives thereof, or any combinations thereof.

17. The method of claim 14, wherein the coating layer is formed of cobalt or cobalt alloy.

18. The method of claim 14, wherein the coating layer is formed by a plasma spray process, a sputtering process, a PVD process, a CVD process, a PE-CVD process, an ALD process, a PE-ALD process, an electroplating or electrochemical plating process, or an electroless deposition process.

19. The method of claim 14, further comprising:
roughening the coating layer by an abrasive blasting process.

20. The method of claim 19, further comprising:
installing the body having the coating layer in the processing chamber prior to processing a substrate in the processing chamber.
